(19) United States
(12) Patent Application Publication
(10) Pub. No.: US 2025/0069913 A1
(43) Pub. Date: Feb. 27, 2025

(54) HEATER SYSTEM FOR GAS PROCESSING COMPONENTS

(71) Applicant: WATLOW ELECTRIC MANUFACTURING COMPANY, St. Louis, MO (US)

(72) Inventors: Terry COLHOUR, Fulton, MO (US); Eric ELLIS, Columbia, MO (US)

(73) Assignee: WATLOW ELECTRIC MANUFACTURING COMPANY, St. Louis, MO (US)

(21) Appl. No.: 18/941,266

(22) Filed: Nov. 8, 2024

Related U.S. Application Data
(63) Continuation of application No. PCT/US2023/066780, filed on May 9, 2023.
(60) Provisional application No. 63/339,625, filed on May 9, 2022.

(51) Int. Cl. H01L 21/67; G01K 7/04; H05B 3/34

(52) U.S. Cl. CPC H01L 21/67109; G01K 7/04; H05B 3/34; H05B 2203/005; H05B 2203/016

(57) ABSTRACT

A heater system for semiconductor processing includes a base, a plurality of gas processing components, and a heater. The plurality of gas processing components are secured to the base. The heater is disposed along a length of the base and between the base and the plurality of gas processing components. The heater is configured to provide heat to the plurality of gas processing components.

### CROSS-REFERENCE TO RELATED APPLICATIONS

This application is a continuation application of International Application No. PCT/US2023/066780 filed on May 9, 2023, which claims priority to and the benefit of U.S. Patent Application No. 63/339,625, filed on May 9, 2022. The disclosures of the above applications are incorporated herein by reference in their entireties.

### FIELD

The present disclosure relates to a heater system and more particularly a rail-mounted heater system for use in pressure control manifolds in the delivery of critical fluids for industrial processes.

### BACKGROUND

The statements in this section merely provide background information related to the present disclosure and may not constitute prior art.

Pressure control manifolds are used in industrial processes to control, indicate pressure, filter, and isolate gases flowing through process gas lines. Such industrial processes include, by way of example, semiconductor, nano-technology, and solar process tools. These pressure control manifolds are also referred to as “gas sticks” in the art.

With semiconductor processing, each piece of equipment within the system is controlled to tight tolerances. As process gases flow through gas supply lines, the gas is tightly controlled to specific temperatures and mass flow rates. When process gases cool, condensation tends to form on the inside of the gas lines, which can inhibit the desired flow and chemistry of process gases. Accordingly, heaters have been used along the gas sticks to maintain temperatures above a certain level to inhibit such condensation. However, a variety of shapes and sizes of gas sticks are often used along a rail-mounted system, thus resulting in complex heater configurations and mountings.

These issues related to rail-mounted heaters for use in gas sticks, among other issues related to the process gas system, are addressed by the present disclosure.

### SUMMARY

This section provides a general summary of the disclosure and is not a comprehensive disclosure of its full scope or all of its features.

In one form, the present disclosure provides a heater system for semiconductor processing. The heater system comprises a base, a plurality of gas processing components secured to the base, and a heater. The heater is disposed along a length of the base and between the base and the plurality of gas processing components. The heater is configured to provide heat to the plurality of gas processing components.

In variations of the heater system of the above paragraph, which may be implemented individually or in any combination: the base is in a form of a rail, and the heater is disposed along a length of the rail; the heater is a polyimide heater; the heater extends an entire length of the base; the heater is selected from the group consisting of a layered heater, a cartridge heater, a tubular heater, and a cable heater; the heater includes a continuous heating circuit; the heater includes a plurality of heating zones, each heating zone corresponds to a respective gas processing component; the plurality of heating zones are operable independent of each other; the plurality of gas processing components comprise at least one of a mass flow controller, a regulator, a valve, and a pressure transducer; a plurality of interface blocks are secured to the base and disposed between the heater and a corresponding gas processing component, a processing gas is configured to flow through each interface block; the plurality of gas processing components are secured to the base by mechanical fasteners; the mechanical fasteners extend through the heater; power leads configured to provide power to the heater, the power leads connected to an end of the heater or a center area of the heater; the power leads extend parallel or normal to the heater; the power leads comprise a first power lead made of a first conductive material and a second power lead made of a second conductive material that is different than the first conductive material, the first and second power pins form a thermocouple junction to determine a temperature of the heater; a thermally and electrically insulating material surrounding the first and second power pins proximate the thermocouple junction; the first and second power leads are connected to the heater via first and second conductive tabs, respectively; the first and second conductive tabs are flat and flexible; the first conductive tab is made of the first conductive material and the second conductive tab is made of the second conductive material; the first conductive tab is welded to the first power lead and the second conductive tab is welded to the second power lead; and a bottom side of the heater and the first and second conductive tabs are covered using a dielectric material and bonded to the base.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a perspective view of a heater system for use in gas sticks of semiconductor processing equipment according to the principles of the present disclosure;

FIG. 2 is a bottom view of a rail to which the heater system of FIG. 1 is mounted;

FIG. 3 is an exploded side view of the heater system of FIG. 1;

FIG. 4 is a top view of a rail and a heater of the heater system of FIG. 1;

FIG. 5A is a perspective view of another heater having temperature sensing power leads constructed according to the principles of the present disclosure;

FIG. 5B is a schematic view of the heater of FIG. 5A bonded to a rail;

FIG. 5C is a perspective view of another heater system according to the principles of the present disclosure;

FIG. 6 is a perspective view of a portion of yet another heater system according to the principles of the present disclosure;

FIG. 7 is a top view of another heater according to the principles of the present disclosure; and

FIG. 8 is a perspective view of another heater system according to the principles of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

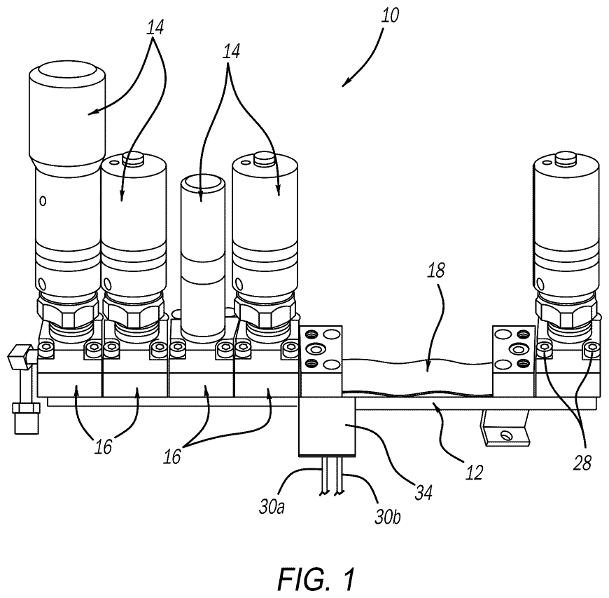

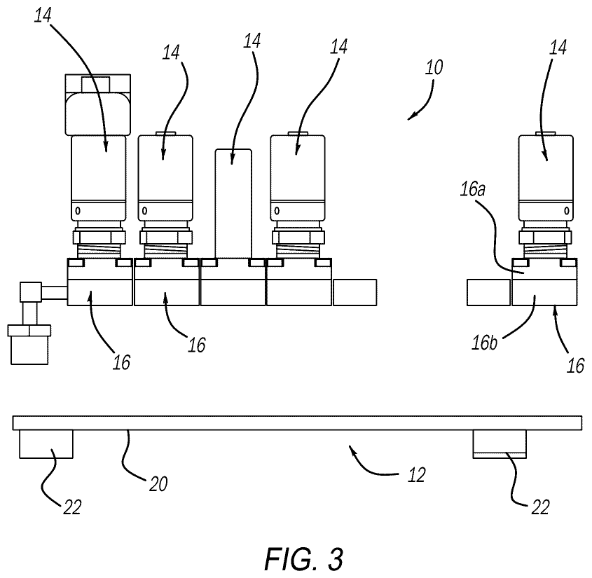

With reference to FIGS. 1-4, a heater system 10 is illustrated. In one example, the heater system 10 is used with rail-mounted gas sticks in semiconductor processing equipment. That is, the heater system 10 is used to facilitate the production of semiconductor chips for a variety of electronic products. As shown, the heater system 10 comprises a base 12 such as a rail, a plurality of gas processing components 14, a plurality of interface blocks 16, a heater or heating strip 18, and power leads 30.

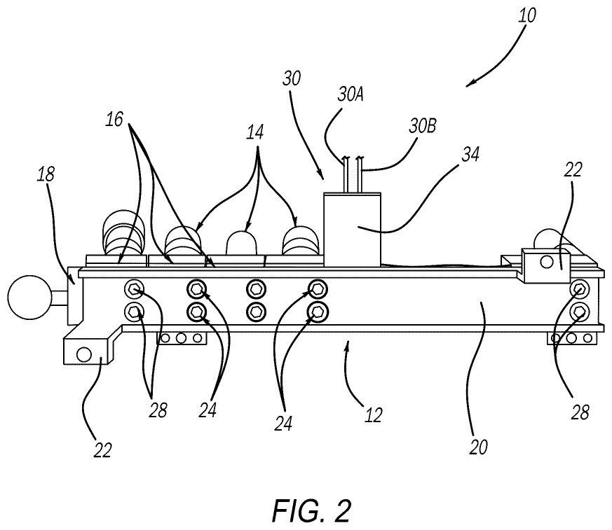

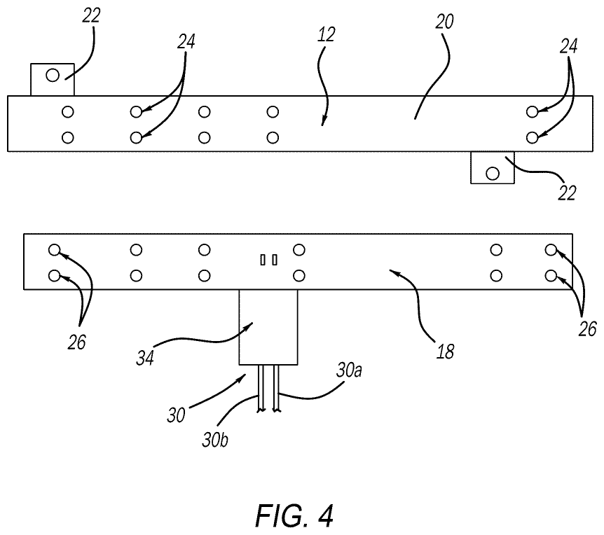

The rail 12 is made of a metal material such as aluminum, for example, and includes an elongated body 20 and a plurality of mounts 22. In the example illustrated, the body 20 has a generally rectangular-shape and includes a plurality of pairs of openings 24 (FIGS. 2 and 4) disposed along a length of the body 20. Each opening 24 of the pairs of openings 24 extends from an upper surface of the body 20 to a lower surface of the body 20. The mounts 22 are configured to secure the heater system 10 to a support surface (not shown) and are located at various points along the body 20. For example, one or more mounts 22 may be located at a first side of the body 20 at or near a first end of the body 20 while one or more mounts 22 may be located at an opposed second side of the body 20 at or near an opposed second end of the body 20.

The gas components 14 are secured to the interface blocks 16 and are configured to control, indicate pressure, filter, and isolate process gases flowing through a gas supply line (not shown). In the example illustrated, some of the gas components 14 are threaded into respective interface blocks 16. In some variations, at least a portion of the process gas is stored in one or more of the gas components 14. The gas components 14 can comprise, by way of example, one or more of mass flow controllers (MFCs), regulators (e.g., electronic regulators), mixing chambers, pressure transducers, gas filters, valves (e.g., manual or pneumatic valves), and the like.

The plurality of interface blocks 16 are made of a metal material such as steel, for example, and are secured to the rail 12. The plurality of interface blocks 16 are also disposed between the heater 18 and the plurality of gas components 14. The interface blocks 16 are fluidly connected to each other such that the interface blocks 16 cooperate to form the gas supply line that process gas flows through. In the example illustrated, each interface block 16 includes an upper block 16a and a lower block 16b. The upper block 16a is secured to a respective gas processing component 14 and the lower block 16b is secured to the upper block 16a and the rail 12. In some forms, the process gas flows through each of the upper block 16a and the lower block 16b. In other forms, the process gas flows through only one of the upper block 16a and the lower block 16b.

With reference to FIGS. 1, 2 and 4, the heater 18 is disposed along a length of the rail 12 between the rail 12 and the interface blocks 16 (i.e., the heater 18 extends in a direction parallel to a length of the rail 12). In the example illustrated, the heater 18 is sandwiched between the rail 12 and the interface blocks 16. In some forms, the heater 18 is bonded to the rail 12 using an adhesive material such as a dielectric material, for example. The heater 18 is configured to provide heat to the interface blocks 16 and the plurality of gas components 14. In some forms, an insulating material (not shown) is disposed between the heater 18 and the rail 12 and a conductive material (e.g., conductive paste) is disposed between the heater 18 and the interface blocks 16. In this way, heat generated by the heater 18 flows toward the interface blocks 16 and the gas components 14 in a uniform manner. In the example illustrated, the heater 18 is a polyimide heater and extends an entire length of the rail 12. It should be understood, however, that the heater 18 could be any form of a heater, including by way of example, a layered heater, a cartridge heater, a tubular heater, or a cable heater, among others. Therefore, the illustration and description of a polyimide heater should not be construed as limiting the scope of the present disclosure.

In some forms, the heater 18 may extend a portion of the length of the rail 12 and may be any other suitable heater configured to provide heat to the interface blocks 16 and the plurality of gas components 14. In the example illustrated, the heater 18 includes a continuous heating circuit and is a formed of a thin profile. In this way, the heater 18 can be disposed along the length of the rail 12 between the rail 12 and the interface blocks 16 without interfering with the mounting of the interface blocks 16 and the gas components 14 to the rail 12. In some examples, the heater 18 may be bonded to the rail 12 by an adhesive.

As shown in FIG. 4, the heater 18 includes a plurality of pairs of openings 26 disposed along a length of the heater 18. Each pair of openings 26 is aligned with a respective pair of openings 24 of the body 20. In this way, mechanical fasteners 28 (FIGS. 1 and 2) such as bolts, screws, or rivets, for example, extend through respective interface blocks 16, a respective pair of openings 26 of the heater 18, and a respective pair of openings 24 of the body 20, thereby securing the interface blocks 16, the heater 18, and the rail 12 to each other. In some forms, the heater 18 includes a plurality of heating zones (not shown) that may include additional power leads and busing arrangements depending on the zone configuration. For example, each heating zone corresponds to a respective gas stick 14 and is operable independent of the other heating zones. A plurality of power leads are connected to respective heating zones of the heater 18 and may be independently controlled using a switch, for example, to heat the respective heating zones based requirements of the process gas flowing through the gas supply line.

Power leads 30 are connected to a power source (not shown) and the heater 18 (via conductive tabs) is are configured to provide power to the heater 18 to generate heat. In the example illustrated, the power leads 30 are connected to the heater 18 at a center area of the heater 18 and extend normal to the heater 18. In some forms, the power leads 30 are connected to an end of the heater 18 and extend parallel to the heater 18. In one form, the power leads 30 comprise a first power lead or pin 30a made of a first conductive material and a second power lead or pin 30b made of a second conductive material that is different than the first conductive material. The first and second power pins 30a, 30b thus form a thermocouple junction. In this way, changes in voltage at the thermocouple junction are detected to determine a temperature of the heater 18 at a predetermined location. In the example illustrated, the thermocouple junction determines the temperature of the heater 18 at or near a center of the heater 18. In some forms, the thermocouple junction determines the temperature of the heater 18 at an end of the heater 18. In the example illustrated, a thermally and electrically insulating cover 34 surrounds the first and second power pins 30a, 30b proximate the thermocouple junction. The thermally and electrically insulating cover 34 may be made of a silicone rubber, for example, and may also provide strain relief to the power pins 30a, 30b.

The arrangement of the heater system 10 of the present disclosure provides the benefit of distributing heat generated from the heater 18 to the interface blocks 16 and the gas components 14.

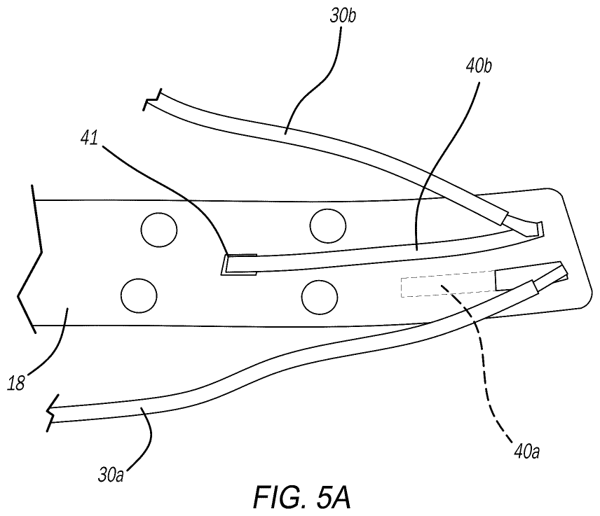

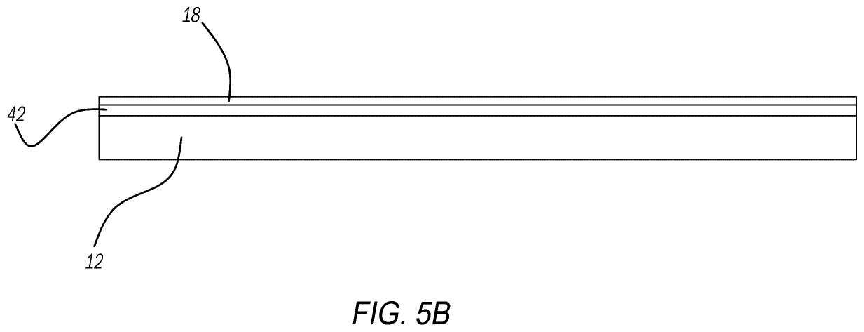

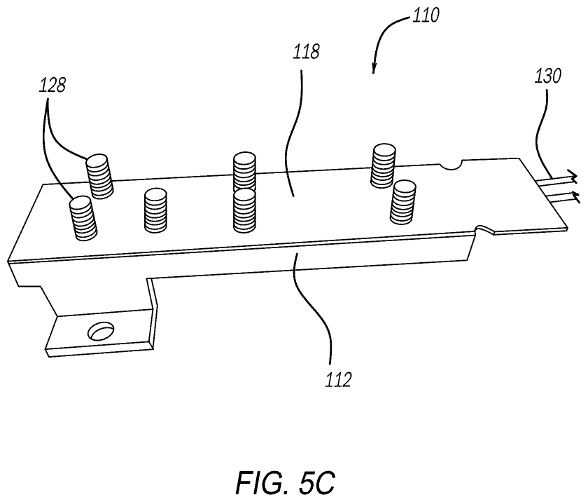

Referring now to FIGS. 5A-5B, another form of the present disclosure includes temperature sensing power leads. The power leads 30a, 30b are electrically connected to the heater 18 via respective thin, flexible conductive tabs 40a, 40b positioned between the rail 12 and the heater 18. In the example illustrated, the conductive tab 40a is made of the same conductive material as the power lead 30a and is welded to the power lead 30a. The location where the conductive tab 40a is welded to the power lead 30a is covered using a dielectric material, for example. In one form, the conductive tab 40b is made of the same conductive material as the power lead 30b, which is a material different from the power lead 30a. For example, in one form, the conductive tab 40a may be a chromel material and the conductive tab 40b is an alumel material (Type K thermocouple). A first end of the conductive tab 40b is welded to a termination end of the heater 18 and a second end of the conductive tab 40b is welded to the power lead 30b. In this way, a thermocouple junction 41 is formed at the location where the first end of the conductive tab 40b is welded to the termination end of the heater 18. The location where the conductive tab 40b is welded to the power lead 30b is covered using a dielectric material, for example. In the example illustrated, the first and second conductive tabs 40a, 40b extend parallel to the heater 18. In other forms, the first and second conductive tabs 40a, 40b extend orthogonal, or at any other angle, to the heater 18. With reference to FIG. 5B, a bottom side of the heater 18 and the conductive tabs 40a, 40b are covered using a dielectric material 42. In this way, the heater 18 and the conductive tabs 40a, 40b are protected and the heater 18 is bonded to the rail 12. Additional forms of temperature sensing power leads are disclosed in U.S. Pat. No. 10,728,956, which is commonly owned with the present application and the contents of which are incorporated herein by reference in their entirety.

With reference to FIG. 5C, another heater system 110 is illustrated. The structure and function of the heater system 110 is generally similar or identical to that of heater system 10 described above, apart from any exception noted below.

The heater system 110 comprises a rail 112, a plurality of gas processing components (not shown), a plurality of interface blocks (not shown), a heater or heating strip 118, and power leads 130. The rail 112 and the heater 118 are shorter in length than the rail 12 and the heater 18 illustrated above. Mechanical fasteners 128 extend through the rail 112, the gas processing components, the interface blocks and the heater 118, thereby securing the rail 112, the gas processing components, the interface blocks, and the heater 118 to each other. Power leads 130 are connected to a power source (not shown) and the heater 118 (via conductive tabs), and are configured to provide power to the heater 118 to generate heat. In the example illustrated, the power leads 130 are connected to an end of the heater 118 and extend parallel to the heater 118.

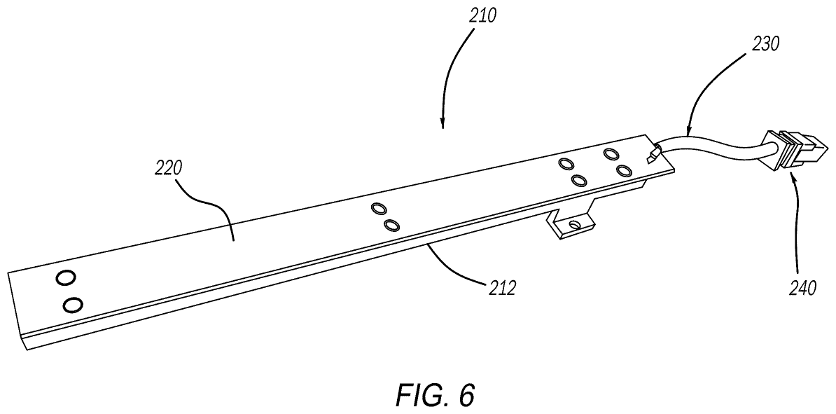

With reference to FIG. 6, another heater system 210 is illustrated which is elongated and mounted to the rail 212 (interface blocks 16 and gas components 14 not shown for purposes of clarity). In this form, the power leads 230 extend along the same direction as the polyimide heater 220 and exit out an end portion rather than through the side, normal to the polyimide heater 220 as shown in FIG. 1. As further shown, an electrical connector 240 may be provided with the power leads 230 for ease of connection to a power source (not shown) and a controller (not shown).

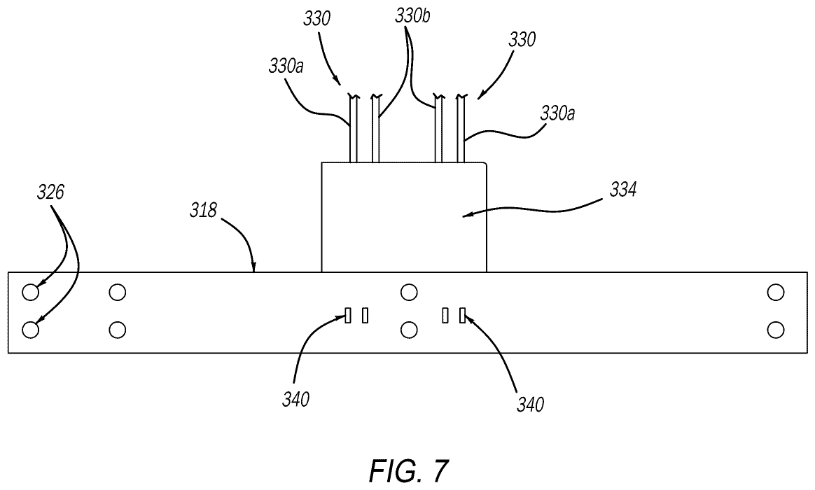

With reference to FIG. 7, another heater 318 is illustrated. The heater 318 may be incorporated into the heater system 10 described above instead of the heater 18. The structure and function of the heater 318 may be similar or identical to that of heater 18 described above, apart from any exceptions noted below.

The heater 318 includes a plurality of pairs of openings 326 disposed along a length of the heater 318. Each pair of openings 326 is aligned with a respective pair of openings 24 of the body 20. Power leads 330 are connected to a power source (not shown) and the heater 318, and are configured to provide power to the heater 318 to generate heat. In the example illustrated, the power leads 330 are connected to a respective heating zone 340 of the heater 318 at or near a center area of the heater 318 and extend normal to the heater 318. For example, each heating zone 340 corresponds to a respective gas processing component and is operable independent of the other heating zones 340. Each power lead 330 comprises a first power lead 330a made of a first conductive material and a second power lead 330b made of a second conductive material that is different than the first conductive material. The first and second power pins 330a, 330b form a thermocouple junction. In this way, changes in voltage at the thermocouple junction are detected to determine a temperature of the heater 318 at a respective heating zone 340. In the example illustrated, a thermally and electrically insulating cover 334 surrounds the first and second power pins 330a, 330b of each power lead 330 proximate the thermocouple junction.

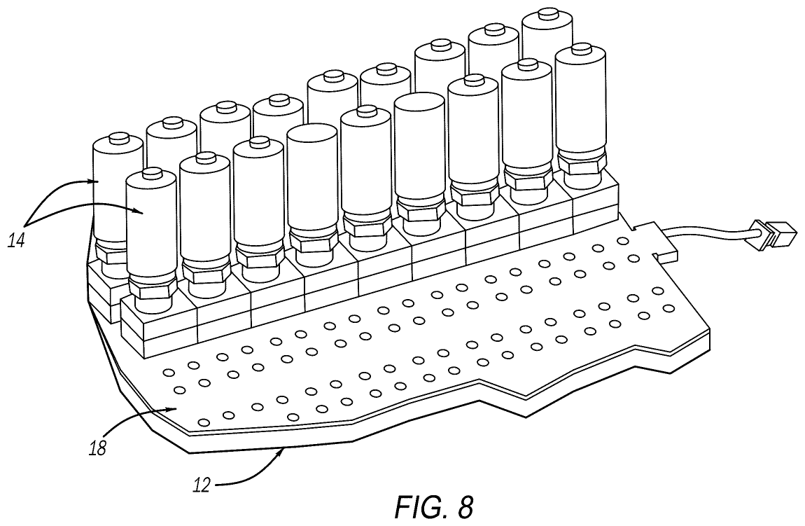

It should be understood that although the base 12 is shown above as a rail, the base 12 could be a plate like configuration with the gas processing components 14 arranged in multiple rows as shown in FIG. 8. In one example, such base 12 is rectangular shape although it should be understood that the base 12 could be any other suitable shape such as triangular or square. It should be also understood that, in some configurations, the gas processing components 14 could be arbitrarily arranged on the base 12 as opposed to arranged in rows. The heater 18 is positioned between the gas processing components 14 and the base 12.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A heater system for semiconductor processing, the heater system comprising:
a base;
a plurality of gas processing components secured to the base; and
a heater disposed on the base, the heater being located between the base and the plurality of gas processing components, the heater configured to provide heat to the plurality of gas processing components.

2. The heater system of claim 1, wherein the base is in a form of a rail, and the heater is disposed along a length of the rail.

3. The heater system of claim 1, wherein the heater is a polyimide heater.

4. The heater system of claim 1, wherein the heater is selected from the group consisting of a layered heater, a cartridge heater, a tubular heater, and a cable heater.

5. The heater system of claim 1, wherein the heater extends an entire length of the base.

6. The heater system of claim 1, wherein the heater includes a continuous heating circuit.

7. The heater system of claim 1, wherein the heater includes a plurality of heating zones, and wherein each heating zone corresponds to a respective gas processing component.

8. The heater system of claim 7, wherein the plurality of heating zones are operable independent of each other.

9. The heater system of claim 1, wherein the plurality of gas processing components comprise at least one of a mass flow controller, a regulator, a valve, a gas filter, and a pressure transducer.

10. The heater system of claim 1, further comprising one or more interface blocks secured to the base and disposed between the heater and a corresponding gas processing component, wherein a processing gas is configured to flow through each interface block.

11. The heater system of claim 1, wherein the plurality of gas processing components are secured to the base by mechanical fasteners.

12. The heater system of claim 11, wherein the mechanical fasteners extend through the heater.

13. The heater system of claim 1, further comprising power leads configured to provide power to the heater, the power leads connected to an end of the heater or a center area of the heater.

14. The heater system of claim 13, wherein the power leads extend parallel or normal to the heater.

15. The heater system of claim 13, wherein the power leads comprise a first power pin made of a first conductive material and a second power pin made of a second conductive material that is different than the first conductive material, the first and second power pins form a thermocouple junction to determine a temperature of the heater.

16. The heater system of claim 15, further comprising a thermally and electrically insulating material surrounding the first and second power pins proximate the thermocouple junction.

17. The heater system of claim 15, wherein the first and second power leads are connected to the heater via first and second conductive tabs, respectively.

18. The heater system of claim 17, wherein the first and second conductive tabs are flat and flexible.

19. The heater system of claim 17, wherein the first conductive tab is made of the first conductive material and the second conductive tab is made of the second conductive material.

20. The heater system of claim 17, wherein the first conductive tab is welded to the first power lead and the second conductive tab is welded to the second power lead, and wherein a bottom side of the heater and the first and second conductive tabs are covered using a dielectric material and bonded to the base.
